(19) United States
(12) Patent Application Publication
(10) Pub. No.: US 2016/0370398 A1
(43) Pub. Date: Dec. 22, 2016

(54) PRINTED CIRCUIT BOARD HAVING AN OSCILLATION-DECOUPLED ELECTRONIC COMPONENT

(71) Applicant: ROBERT BOSCH GMBH, Stuttgart (DE)

(72) Inventors: Marc Dressier, Stuttgart (DE); Manfred Spraul, Hildesheim (DE)

(21) Appl. No.: 14/901,569

(22) PCT Filed: Jun. 4, 2014
(86) PCT No.: PCT/EP2014/061537

§ 371 Date: Dec. 28, 2015

(30) Foreign Application Priority Data
Jun. 25, 2013 (DE) 10 2013 212 053.2

(51) Int. Cl. G01P 1/00; H05K 1/18

(52) U.S. Cl. CPC G01P 1/003; H05K 1/181; H05K 2201/10151

(57) ABSTRACT

The invention relates to an arrangement having a printed circuit board and having an oscillation-decoupled electronic component. According to the invention, the arrangement has a substructure in an oscillatable form. The substructure is connected to the printed circuit board on a surface region of the printed circuit board. The substructure has at least one holding plate for the component. The substructure is designed to decouple the component from structure-borne sound acting on the substructure from the printed circuit board. The substructure is in the form of a 3-dimensional moulded interconnect device structure that has at least one electrical connecting line, formed by an electrically conductive layer, that connects the printed circuit board to the component.

### BACKGROUND OF THE INVENTION

The invention relates to an arrangement having a printed circuit board and having an oscillation-decoupled electronic component.

In printed circuit boards known from the prior art having an electronic component, in particular a sensor, for example, an acceleration sensor, the problem exists that mechanical interfering oscillations transferred to the printed circuit board are not to reach the electronic component, in particular the sensor, insofar as the sensor can receive these interfering oscillations as an interference signal, which can be overlaid on a useful signal to be detected by the sensor and can therefore interfere with the analysis of the useful signal.

Spring and/or damping elements are known from the prior art to solve the problem, which are arranged in the form of a gel, an elastomer, or an elastomeric foam between the component and the printed circuit board.

### SUMMARY OF THE INVENTION

According to the invention, the arrangement of the type mentioned at the outset has a substructure which is designed to be capable of oscillation. The substructure is connected to the printed circuit board on a surface region of the printed circuit board. The substructure has at least one receptacle plate for the component. The substructure is designed to decouple the component from a structural noise acting from the printed circuit board on the substructure—preferably for frequencies greater than 500 Hz. The receptacle plate is preferably connected to the component. The substructure is preferably formed from plastic, wherein the component, in particular at least one electrical terminal of the component, is connected by means of at least one electrical connecting line to the printed circuit board, in particular an electrical terminal of the printed circuit board. The substructure is preferably designed in particular as a three-dimensional molded interconnect device structure, which has the at least one electrical connecting line. The connecting line is preferably designed as an electrically conductive layer, in particular a surface layer, which is connected to the substructure, in particular a surface of the substructure. Furthermore, the at least one electrical connecting line is preferably applied to the substructure by means of electroplating, thermal spraying, in particular plasma spraying, or cold gas spraying. For the electroplating, the substructure can be surface structured by means of a laser, for example, so that the electrically conductive layer can be created in a step following the surface structuring by means of electroplating.

For the thermal spraying, the surface of the substructure can be roughened in the region of the electrically conductive layer to be created, to thus create a nucleation for layer growth thereon. The roughening can be carried out by means of a laser, for example, as positive structuring.

The electrical terminal of the printed circuit board is preferably formed by a solder pad, in particular a conductor track section.

The substructure designed as capable of oscillation, in particular as elastic, can thus advantageously form a spring which decouples the electronic component from the printed circuit board or additionally can form a damper, and can electrically connect the electronic component to the printed circuit board with its property as an MID substructure. A separately formed, in particular flexible connecting line, for example, a lead, which extends from the printed circuit board up to the component, can thus advantageously be omitted.

The substructure is preferably formed by a plastic, in particular a plastic produced by injection molding. The plastic is, for example, polyethylene, polypropylene, polyamide, polybutylene terephthalate, ABS (ABS=acrylonitrile butadiene styrene) or LCP (LCP=liquid crystal polymer).

In one preferred exemplary embodiment, the substructure has at least one support leg which extends transversely to a planar extension of the printed circuit board, in particular a printed circuit board plane. The support leg is connected in the region of one end of the support leg to the printed circuit board. The support leg is furthermore preferably at least indirectly connected to the receptacle plate. A torsion spring, or a spring designed as deformable like a bending bar, can thus advantageously be formed by means of the support leg. The receptacle plate having the component is thus advantageously arranged spaced apart from the printed circuit board—preferably spaced apart in parallel to the printed circuit board.

In one preferred embodiment, the substructure has at least one oscillation arm. The oscillation arm is preferably formed onto the support leg and furthermore preferably extends transversely to the support leg. The oscillation arm is at least indirectly connected to the receptacle plate. A spring can thus advantageously be formed by means of the oscillation arm, using which spring the receptacle plate is connected in a springy manner to the printed circuit board transversely to a planar extension of the printed circuit board.

In one preferred embodiment, the oscillation arm is connected by means of at least one connecting element to the receptacle plate. The connecting element connects an end section of the oscillation arm to the receptacle plate. The receptacle plate can advantageously be connected to the oscillation arm in a manner spaced apart from the oscillation arm by means of the connecting element.

The substructure preferably has at least two support legs. The support legs are each connected with an end section facing away from the printed circuit board to opposing end sections of an oscillation arm. In this manner, the oscillation arm can advantageously be supported in each case by a support leg in the region of two opposing ends of the oscillation arm and can oscillate with a longitudinal section, which extends between the support legs, transversely to its longitudinal extension.

In the case of the connection of the oscillation arm at only one end to a support leg, the oscillation arm can oscillate transversely to its longitudinal extension with the end facing away from the support leg. A transverse wave can advantageously propagate on the oscillation arm via the oscillation arm both in the case of the support by two support legs or in the case of the support by only one support leg.

In one preferred embodiment, the substructure has at least two oscillation arms, which are connected to one another, and which each extend in parallel to the printed circuit board plane and which cross over one another. A double spring can thus advantageously be formed, wherein two individual springs of the double spring, each formed by one oscillation arm, are thus connected to one another in series, so that a spring stiffness of the overall spring formed by the oscillation arms is less than that of an individual spring, formed by an individual oscillation arm.

In one preferred embodiment of the substructure, one of the oscillation arms is connected via at least one support leg to the printed circuit board and the other oscillation arm is connected via at least one connecting element to the receptacle plate. Furthermore, the one oscillation arm can preferably form a U shape together with two support legs and the other oscillation arm can form a U shape together with two connecting elements, which are each formed onto the oscillation arm at opposing ends of the other oscillation arm. Furthermore, the openings of the U shapes thus formed face away from one another.

In one preferred embodiment, the substructure has a flatly formed base element, which is connected to the printed circuit board, in particular adhesively bonded, plug-connected, or solder bonded. The base element is preferably connected to at least one support leg of the substructure, furthermore preferably formed onto the at least one support leg. In this manner, the substructure can simply be placed on the printed circuit board and glued and/or soldered to the printed circuit board for the connection to the printed circuit board. The substructure is preferably soldered to the printed circuit board, wherein a solder pad on the printed circuit board is formed for the connection to the substructure, to hold the substructure after soldering. For this purpose, the solder pad has an area dimension which creates a sufficiently strong material bond to the substructure, so that the substructure can remain solidly connected to the printed circuit board even in the event of shocks of the printed circuit board. The solder pad is preferably electrically connected to the connecting line of the substructure, so that both a mechanical connection and also an electrical connection of the substructure to the printed circuit board are created by the soldered bond.

In one preferred embodiment, the substructure has at least one meandering spring element, which at least indirectly connects the receptacle plate to the printed circuit board. The meandering spring element is preferably formed onto the receptacle plate and the printed circuit board. The meandering spring element has, for example, a half-wave shape or a semicircle shape.

The substructure can advantageously be formed without corners by means of the meandering spring element.

In one preferred embodiment, the substructure has at least one S-shaped spring element, wherein the receptacle plate is connected to the printed circuit board at least indirectly via the S-shaped spring element. A spring element formed without corners can advantageously be formed by means of the S-shaped spring element. Furthermore, the spring element, in particular a spring constant of the spring element, can advantageously be easily calculated.

The invention also relates to a substructure according to the above-described type. The substructure is designed to be arranged between an electronic component and a printed circuit board, and has a receptacle plate for the component and is designed to decouple the component from structural noise acting from the printed circuit board on the substructure. The substructure is designed as a three-dimensional molded interconnect device structure and has at least one electrical connecting line, which is designed to connect an electrical terminal of the component to a terminal of the printed circuit board. The electrical connecting line is preferably formed by an electrically conductive layer. For example, the connecting line is created by means of electroplating or thermal spraying on a surface of the substructure. The connecting line can be created in another exemplary embodiment by means of laser subtractive structuring of a substructure which is electroplated with an electrically conductive layer. In another embodiment, the substructure has at least two plastics which are different from one another, wherein the connecting line is formed on at least one plastic. The other plastic is preferably designed to repel the electrically conductive material forming the electrically conductive layer during the electroplating. The connecting line can thus only be formed on the plastic which accepts the material.

In contrast to the above-described arrangement, the substructure does not have a printed circuit board and does not have a component.

### BRIEF DESCRIPTION OF THE DRAWINGS

The invention will now be described hereafter on the basis of figures and further exemplary embodiments. Further advantageous embodiment variants result from the features described in the figures and the dependent claims.

FIG. 1 shows an exemplary embodiment of an arrangement having an electronic component and a substructure, which is designed as springy or additionally damping, and is designed to be connected to a printed circuit board, wherein the substructure has two support legs and one oscillation arm;

FIG. 2 shows an exemplary embodiment of an arrangement having an electronic component and a substructure, which is designed as springy or additionally damping, and is designed to be connected to a printed circuit board, wherein the substructure has two support legs and two oscillation arms crossing over one another;

FIG. 3 shows an exemplary embodiment of an arrangement having an electronic component and a substructure, which is designed as springy or additionally damping, and is designed to be connected to a printed circuit board and which has two oscillation arms, which are each connected to a receptacle plate for an electronic component;

FIG. 4 shows an exemplary embodiment of an arrangement having an electronic component and a substructure, which is designed as springy or additionally damping and has an S-shaped spring element for this purpose;

FIG. 5 shows a diagram having two transfer functions to the substructure according to FIG. 2, which was excited transversely to the axis 12;

FIG. 6 shows a diagram having two transfer functions to the substructure according to FIG. 2, which was excited in the direction of the axis 12.

### DETAILED DESCRIPTION

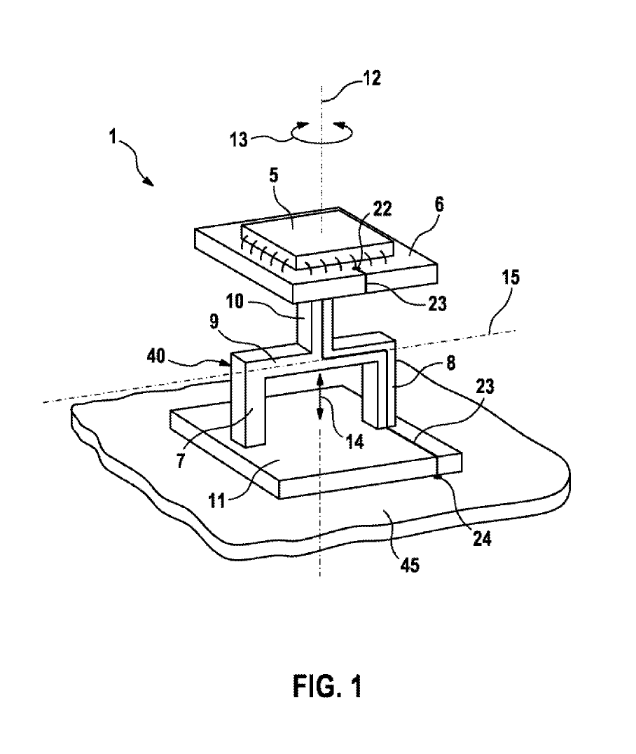

FIG. 1 shows an exemplary embodiment of an arrangement 1. The arrangement 1 comprises an electronic component 5. The electronic component 5 is, for example, an acceleration sensor, in particular a MEMS sensor (MEMS=micro-electromechanical system). The component 5 is connected to a receptacle plate 6 of a substructure 40, which is designed as springy or additionally damping. The substructure 40 also has a support leg 7 and a support leg 8, wherein the support legs 7 and 8 extend in parallel to one another and spaced apart from one another and are each connected at an end section to a base 11, in particular a base plate of the substructure 40, in this exemplary embodiment are formed onto the base 11. The end sections of the support legs 7 and 8 facing away from the base 11 are each connected to one another by means of an oscillation arm 9. The oscillation arm 9 extends with at least one transverse component in relation to the longitudinal extension of the support legs 7 and 8, in this exemplary embodiment transversely, i.e., at a right angle to the longitudinal extension of the support legs 7 and 8. A connecting element 10, which is formed onto the oscillation arm 9, is arranged on the oscillation arm 9 on a longitudinal section of the oscillation arm, which extends between the support legs 7 and 8. The oscillation arm 9 is connected via the connecting element 10 to the receptacle plate 6. The receptacle plate 6 extends in this exemplary embodiment with its planar extension in parallel to the base 11. The base 11 is connected, in particular glued, in this exemplary embodiment to a printed circuit board 45.

The electronic component 5 has electrical terminals, of which the electrical terminal 22 is identified as an example. The terminal 22 is connected by means of an electrical connecting line 23 to a terminal 24. The terminal 24 is formed, for example, by a conductor track section of a conductor track of the printed circuit board 45. The electrical terminals 22 and 24 can create, for example, both the electrical connection and also the mechanical fixation of the substructure with the printed circuit board. The electrical connecting line 23 is formed in this exemplary embodiment as a longitudinally extending copper layer, which is applied by means of electroplating, laser structuring, or thermal spraying, in particular plasma spraying, to the substructure 40. The substructure 40 thus forms a molded interconnect device.

The electronic component 5 can oscillate together with the receptacle plate 6 transversely in relation to a planar extension of the receptacle plate 6, along an axis 12, and can execute a translation movement in this case, in particular a back-and-forth movement 14 along the axis 12. The receptacle plate 6, which jointly forms an oscillating mass together with the electronic component 5, oscillates in this case together with the connecting element 10 on the oscillation arm 9. The oscillation arm 9 thus forms a spring for the oscillation mode corresponding to the above-described oscillation along the axis 12.

The substructure 40 is designed in this exemplary embodiment to form further oscillation modes. For example, the electronic component 5 can execute a pivot movement together with the receptacle plate 6 about the longitudinal axis 15 of the oscillation arm 9, wherein the pivot movement represents a further oscillation mode.

The electronic component 5 can execute a rotational movement 13 together with the receptacle plate 6, also about the axis 12. The rotational movement 13 corresponds in this case to a further oscillation mode of the substructure 40.

The electronic component 5 can thus be effectively decoupled from the printed circuit board 45 for frequencies greater than a predetermined resonant frequency of the substructure 40. The electronic component 5 advantageously remains connected to the printed circuit board 45 via the electrical connections, such as the connecting line 23.

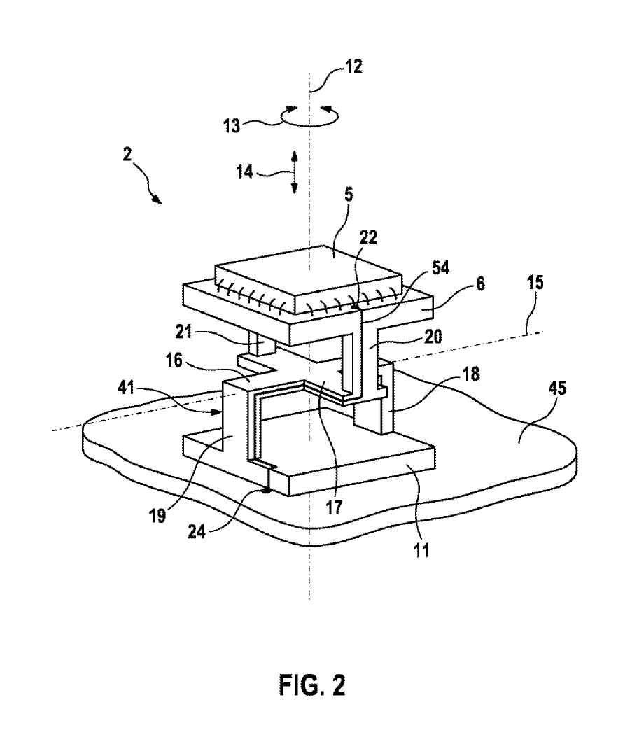

FIG. 2 shows an exemplary embodiment of an arrangement 2. The arrangement 2 has, like the arrangement 1 in FIG. 1, the electronic component 5, which is connected to a receptacle plate 6. The arrangement 2 also has a substructure 41, which is designed differently from the substructure 40 in FIG. 1. The substructure 41 comprises the receptacle plate 6 and a flatly formed base 11, which extends spaced apart in parallel to the receptacle plate 6. The substructure 41 also has two support legs 18 and 19, which are, like the support legs 7 and 8 in FIG. 1, spaced apart from one another and formed onto the base 11. The support legs 18 and 19 extend with at least one transverse component from the base 11 and thus face away from the base 11. In this exemplary embodiment, the support legs 18 and 19 extend transversely to a planar extension of the base 11. The support legs 18 and 19 are connected to one another by means of an oscillation arm 16. The substructure 41 also has a further oscillation arm 17, which is connected to the oscillation arm 16 on a longitudinal section of the oscillation arm 16 and extends with at least one transverse component, in this exemplary embodiment transversely to the longitudinal extension of the oscillation arm 16. The oscillation arms 16 and 17 thus form a cross.

The substructure 41 also has two connecting elements 20 and 21, wherein the connecting element 20 is connected to the oscillation arm 17 in the region of one end of the oscillation arm 17 and the connecting element 21 is connected to the oscillation arm 17 in the region of an end opposite to the connecting element 20. The connecting elements 20 and 21 connect the receptacle plate 6 to the oscillation arm 17, so that the receptacle plate 6 is arranged spaced apart from the oscillation arm 17. The connecting elements 20 and 21 thus cause the oscillation arm 17 to be connected to the receptacle plate 6 in the region of the two ends of the oscillation arm 17. Both the oscillation arm 17 and also the oscillation arm 16 can thus act as a spring jointly, or depending on the oscillation mode of the substructure 41. The electronic component 5 can thus oscillate according to a translational movement 14 along the axis 12, wherein the axis 12 extends transversely to a planar extension of the receptacle plate 6. The electronic component 5 can also execute a rotational movement 13 about the axis 12 together with the receptacle plate 6, or a rotational movement 13 about the axis 15, which extends in the longitudinal extension of the oscillation arm 16. The electronic component 5 can also execute a rotational movement about a longitudinal extension of the oscillation arm 17. The substructure 41 is thus designed to mount the electronic component 5 in an oscillating manner in three rotational and three translational degrees of freedom. The substructure 41 is also designed to electrically connect the electronic component 5 to a printed circuit board 45. The substructure 41 is connected for this purpose by means of the base 11 to the printed circuit board 45, for example, by means of an adhesive or a soldered bond to a solder pad of the printed circuit board.

An electrical terminal 24 of the printed circuit board 45 is also shown, which is connected by means of an electrical connecting line 54 to an electrical terminal 22 of the electrical component 5. The electrical connecting line 54 is created on the substructure 41, for example, by means of electroplating, laser structuring, or thermal spraying, in particular plasma spraying.

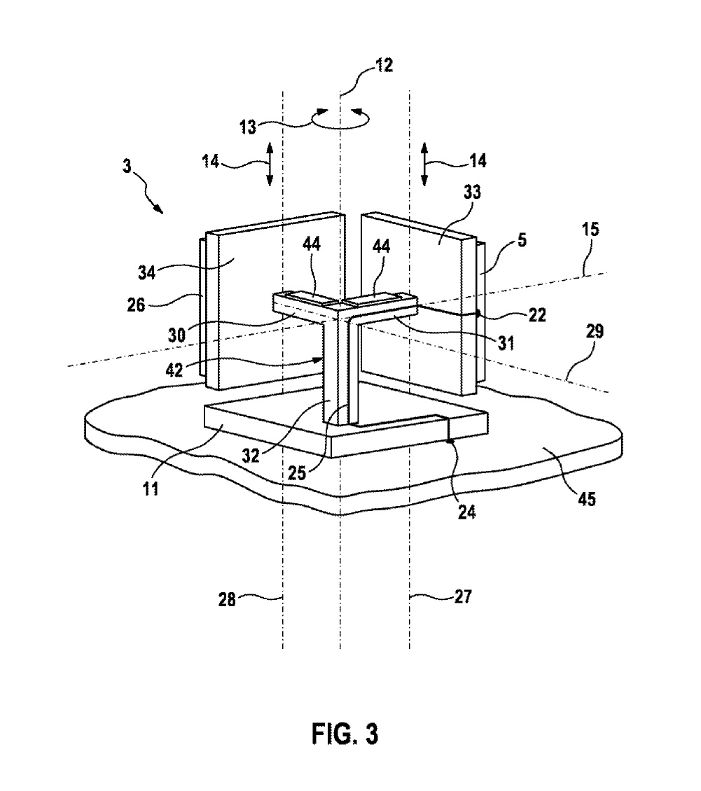

FIG. 3 shows an exemplary embodiment of an arrangement 3, comprising a substructure 42, an electronic component 5, and an electronic component 26. The arrangement 3 can furthermore also comprise the printed circuit board 45, which is partially shown. The electronic components 5 and 26 are respectively connected by means of the substructure 42 in an oscillation-decoupled manner to the printed circuit board 45 and are connected by means of the substructure 42, in particular by means of an electrical connecting line 25, which is connected to the substructure 42, to the printed circuit board 45 and connected thereon to an electrical terminal 24.

The substructure 42 has—in contrast to the substructures 40 and 41—for each of the components 5 and 26, a receptacle plate 33 for the component 5 and a receptacle plate 34 for the component 26. The receptacle plates 33 and 34 are each arranged with the planar extension thereof transversely to a planar extension of the printed circuit board 45 and thus to a planar extension of a base 11 of the substructure 42. For this purpose, the receptacle plate 33 is connected by means of an oscillation arm 31 to a support leg 32 and the receptacle plate 34 is connected by means of an oscillation arm 30 to the support leg 32.

The support leg 32 is—spaced apart from the oscillation arms 30 and 31—connected to the base 11 and formed onto the base 11.

The receptacle plates 33 and 34 each point with the planar extension thereof in directions different from one another, in this exemplary embodiment, the receptacle plates 33 and 34 are arranged orthogonally in relation to one another.

The electronic component 5 is designed, for example, as an acceleration sensor, wherein the acceleration sensor can detect accelerations in two spatial directions different from one another. The electronic component 26 is formed, for example, by a further acceleration sensor, which is designed to detect an acceleration in a direction, in particular transversely to a planar extension of the electronic component 26 and thus transversely to a planar extension of the receptacle plate 34 and along an axis 29. The axis 29 extends along a longitudinal extension of the oscillation arm 30.

The axes 12, 15, and 29 jointly form an orthogonal system in this exemplary embodiment.

In another embodiment, the oscillation arms 31 and 30 are not arranged in parallel to the printed circuit board 45, but rather each extend with a transverse component in relation to a planar extension of the base 11, and thus the printed circuit board plane of the printed circuit board 45. The oscillation arms 30 and 31 thus jointly form a V shape, wherein a plane spanned by the V shape extends orthogonally to the printed circuit board plane or the plane of the base 11. The oscillation arms 30 and 31 can be connected to a structure as shown in FIG. 1 together with the receptacle plates 33 and 34 instead of the support leg 32, so that the oscillation arms 30 and 31 are formed onto the oscillation arm 9 as a standing V shape, instead of the connecting element 10 in FIG. 1.

The substructure 42 also has a damping element 44 in this exemplary embodiment. The damping element 44 is connected to at least one oscillation arm, in this exemplary embodiment to both oscillation arms 31 and 30. The damping element 44 is formed in this exemplary embodiment by a damping layer, in particular an EDPM layer. The damping element 44 can have a further layer in addition to the EPDM layer, so that the damping element 44 is formed as a sandwich element. In this manner, the damping element 44 can achieve a large damping effect with a small thickness extension. In the case of a single damping element, an exemplary thickness extension of the damping element 44 is at least 1.5 times a thickness extension of the oscillation arm 31 or the oscillation arm 30.

A neutral bending fiber of an oscillation movement of the oscillation arm 30 or 31 can thus be located in the damping element 44. The material of the damping element 44 is thus moved by a shear movement about the neutral bending fiber and can thus unfold its damping effect for damping the oscillation movement.

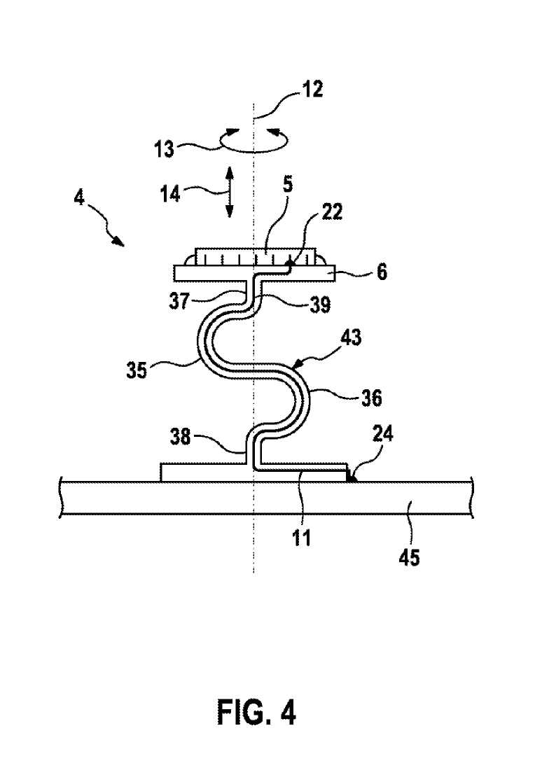

FIG. 4 shows an exemplary embodiment of a substructure 43 as a component of an arrangement 4. The substructure 43 has two meandering spring elements 35 and 36, which jointly form an S shape. The spring element 35 is connected via a connecting element 37 to a receptacle plate 6 of the substructure 43. The receptacle plate 6 carries an electronic component 5, which is connected to the receptacle plate 6. The spring element 36 is connected via a connecting element 38 to a base 11 of the substructure 43.

The receptacle plate 6 is arranged spaced apart in parallel from the base 11 in this exemplary embodiment and encloses the connecting elements 37 and 38 and the spring elements 35 and 36 between one another.

The electronic component 5 can thus oscillate along an axis 12, which extends transversely to the planar extension of the receptacle plate 6, along a translation direction 14, or can also execute a rotational movement 13 about the axis 12. Further oscillation modes of the substructure 43 can comprise, for example, a pivot movement of the receptacle plate 6 about a base point in the region of the base 11, in particular in the region of the connecting element 38. The electronic component 5 is thus advantageously oscillation-decoupled in three translational degrees of freedom and further rotational degrees of freedom from a printed circuit board 45, which is connected to the base 11, for example.

An electrical terminal 22 of the electronic component 5, which is an acceleration sensor, for example, is connected by means of an electrical connecting line 39, which is applied by means of electroplating, laser structuring, or by means of thermal spraying to the substructure 43, to an electrical terminal 24 of the printed circuit board 45. The electrical connecting line 39 extends from the terminal 22, i.e., the electronic component 5, via the receptacle plate 6, i.e., via the connecting element 37, further via the spring elements 35 and 36 and via the connecting element 38 and further via the base 11 up to the terminal 24.

The terminal 24 is connected by means of the connecting line 39, for example, by means of soldering, in particular reflow soldering.

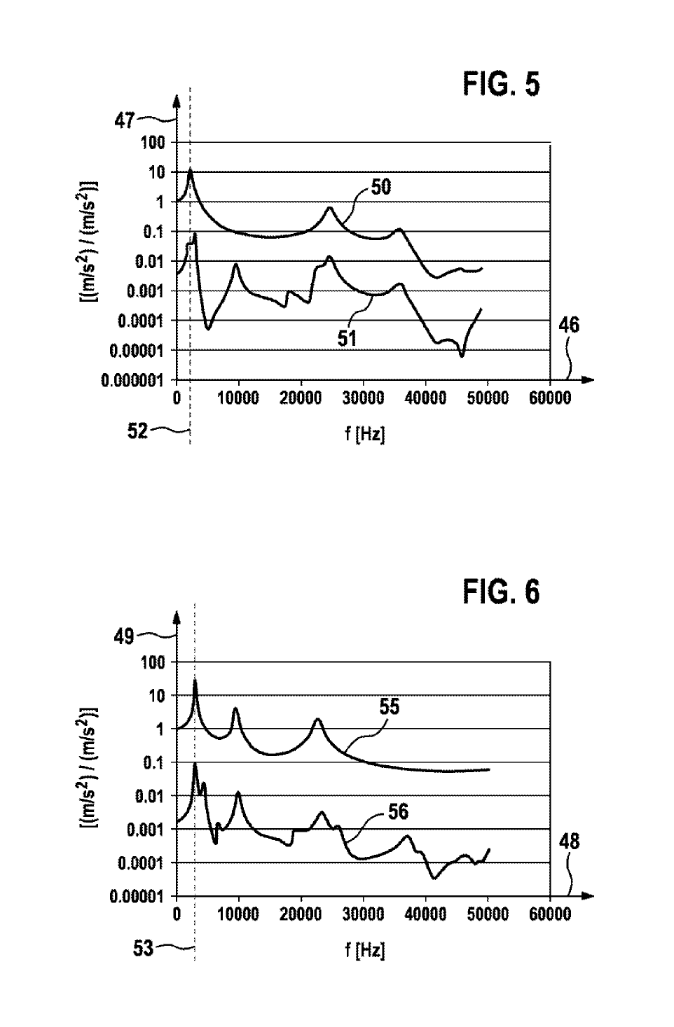

FIG. 5 shows a diagram having two transfer functions 50 and 51 for the substructure 41 according to FIG. 2, which was excited in the direction of the axis 12 on the base 11. A frequency axis 46 and an axis 47, which represents the—dimensionless—transfer function, are shown. A first resonant frequency 52 is visible, wherein the substructure 41 causes a decoupling from the printed circuit board for excitation frequencies greater than the frequency 52. The transfer function 50 represents the response oscillation of the substructure 41 in the direction of the axis 12, the transfer function 51 represents the response oscillation of the substructure 41 transversely to the axis 12, each in relation to an excitation in the direction of the axis 12 at the base 11 of the substructure 41.

FIG. 6 shows a diagram having two transfer functions 55 and 56 for the substructure 41 according to FIG. 2, which was excited transversely to the axis 12 on the base 11. A frequency axis 48 and an axis 49, which represents the—dimensionless—transfer function, are shown. A first resonant frequency 53 is visible, wherein the substructure 41 causes a decoupling from the printed circuit board for excitation frequencies greater than the frequency 52. The transfer function 55 represents the response oscillation of the substructure 41 in the direction of the axis 12, the transfer function 56 represents the response oscillation of the substructure 41 transversely in relation to the axis 12, each in relation to an excitation transversely to the axis 12 on the base 11 of the substructure 41.

A detection frequency range of the sensor is, for example, up to 500 Hz. The resonant frequency 52 or 53 is, for example, between 1000 Hz and 10,000 Hz, so that decoupling is effective for frequencies greater than the resonant frequency. Interference noise greater than the resonant frequency can thus be effectively decoupled from the sensor.

1. An arrangement (1, 2, 3, 4) having a printed circuit board (45) and having an oscillation-decoupled electronic component (5, 26), characterized in that the arrangement (1, 2, 3, 4) has a substructure (40, 41, 42, 43), which is configured to be capable of oscillation, which is connected to the printed circuit board (45) on a surface region of the printed circuit board (45), and which has at least one receptacle plate (6, 33, 34) for the component (5, 26) and is configured to decouple the component (5, 26) from structural noise acting from the printed circuit board (45) on the substructure (40, 41, 42, 43), wherein the receptacle plate (6) is connected to the component (5, 26), and the substructure (40, 41, 42, 43) is formed from plastic, wherein the component is connected by at least one electrical connecting line (23, 25, 39, 54), which is formed by an electrically conductive layer, to the printed circuit board (45), and wherein the substructure (40, 41, 42, 43) is a three-dimensional molded interconnect device structure, which has the at least one electrical connecting line (23, 25, 39, 54).

2. The arrangement (1, 2, 3, 4) as claimed in claim 1, characterized in that the substructure (40, 41, 42, 43) has at least one support leg (7, 8, 18, 19, 32), which extends transversely to a planar extension of the printed circuit board (45), and which is connected in a region of one end of the support leg (7, 8, 18, 19, 32) to the printed circuit board (45) and is at least indirectly connected to the receptacle plate (6, 33, 34).

3. The arrangement (1, 2, 3, 4) as claimed in claim 1, characterized in that the substructure (40, 41, 42, 43) has at least one oscillation arm (9, 16, 17, 30, 31), which is formed onto the support leg and extends transversely to the support leg (7, 8, 18, 19, 32) and is at least indirectly connected to the receptacle plate (6, 33, 34).

4. The arrangement (1, 2, 3, 4) as claimed in claim 3, characterized in that the oscillation arm (9, 16, 17, 30, 31) is connected by a connecting element (10, 20, 21), which connects an end section of the oscillation arm (9, 16, 17, 30, 31) to the receptacle plate (6, 33, 34), to the receptacle plate (6, 33, 34).

5. The arrangement (1, 2, 3, 4) as claimed in claim 1, characterized in that the substructure (40, 41, 42, 43) has at least two support legs (7, 8, 18, 19, 32), which are each connected with an end section facing away from the printed circuit board (45) to opposing end sections of an oscillation arm (9, 16, 17, 30, 31).

6. The arrangement (1, 2, 3, 4) as claimed in claim 1, characterized in that the substructure (40, 41, 42, 43) has at least two oscillation arms (9, 16, 17, 30, 31), which are connected to one another, and which each extend in parallel to the printed circuit board plane and which cross over one another.

7. The arrangement (1, 2, 3, 4) as claimed in claim 6, characterized in that one of the oscillation arms (9, 16, 17, 30, 31) is connected via at least one support leg (7, 8, 18, 19, 32) to the printed circuit board (45) and an other oscillation arm (9, 16, 17, 30, 31) is connected via at least one connecting element (10, 20, 21) to the receptacle plate (6, 33, 34).

8. The arrangement (1, 2, 3, 4) as claimed in claim 1, characterized in that the substructure (40, 41, 42, 43) has a flatly formed base element (11), which is connected to the printed circuit board (45).

9. The arrangement (1, 2, 3, 4) as claimed in claim 1, characterized in that the substructure (40, 41, 42, 43) has at least one meandering spring element (35, 36), wherein the receptacle plate (6, 33, 34) is connected by the spring element (35, 36) at least indirectly to the printed circuit board (45).

10. The arrangement (1, 2, 3, 4) as claimed in claim 1, characterized in that the substructure (40, 41, 42, 43) has at least one S-shaped spring element (35, 36), wherein the receptacle plate (6, 33, 34) is connected to the printed circuit board (45) at least indirectly via the spring element (35, 36).

11. A substructure (40, 41, 42, 43) for an arrangement (1, 2, 3, 4) having a printed circuit board (45) and having an oscillation-decoupled electronic component (5, 26), wherein the substructure (40, 41, 42, 43) is configured to be arranged between at least one electronic component (5, 25) and a printed circuit board (45), wherein the substructure has a receptacle plate (6, 33, 34) for the component (5, 26) and is designed to decouple the component (5, 26) from structural noise acting from the printed circuit board (45) on the substructure (40, 41, 42, 43), and wherein the substructure (40, 41, 42, 43) is a three-dimensional molded interconnect device structure, and has at least one electrical connecting line formed by an electrically conductive layer, which is designed to connect an electrical terminal (22) of the component (5, 26) to a terminal (24) of the printed circuit board (45).
